(19) United States
(12) Patent Application Publication
(10) Pub. No.: US 2025/0072146 A1
(43) Pub. Date: Feb. 27, 2025

(54) LIGHT DETECTING DEVICE

(71) Applicant: SONY SEMICONDUCTOR SOLUTIONS CORPORATION, Kanagawa (JP)

(72) Inventors: Takayuki OGASAHARA, Kanagawa (JP); Kaito YOKOCHI, Kanagawa (JP); Koji MIYATA, Kanagawa (JP); Seiki TAKAHASHI, Kanagawa (JP); Hiroaki TAKASE, Kanagawa (JP)

(73) Assignee: SONY SEMICONDUCTOR SOLUTIONS CORPORATION, Kanagawa (JP)

(21) Appl. No.: 18/847,627

(22) PCT Filed: Mar. 16, 2023
(86) PCT No.: PCT/JP2023/010231

§ 371 Date: Sep. 16, 2024

(30) Foreign Application Priority Data
Apr. 4, 2022 (JP) 2022-062597

(51) Int. Cl. H01L 27/146

(52) U.S. Cl. CPC H01L 27/14625; H01L 27/14621; H01L 27/14645

(57) ABSTRACT

A light detecting device comprises a plurality of pixels that include first pixels that sense light in a first wavelength range, and a second pixel that senses light in a second wavelength range different than the first wavelength range. The second pixel is surrounded by six pixels of the first pixels. The light detecting device comprises first nanostructures that redirect light incident to the first pixels.

### CROSS REFERENCE TO RELATED APPLICATIONS

This application claims the benefit of Japanese Priority Patent Application JP2022-062597 filed Apr. 4, 2022, the entire contents of which are incorporated herein by reference.

### TECHNICAL FIELD

The present disclosure relates to a light detecting device.

### BACKGROUND ART

There has been proposed an apparatus including a meta-optical element being a diffractive element utilizing a nanostructure having a sub-wavelength shape dimension (PTL 1).

### CITATION LIST

### Patent Literature

[PTL 1]Japanese Unexamined Patent Application Publication No. 2021-140152

### SUMMARY

### Technical Problem

A light detecting device is required to have improved detection performance.

It is desirable to provide a light detecting device having favorable detection performance.

### Solution to Problem

A photodetector according to an embodiment of the present disclosure includes: a first pixel including a first filter that transmits light of a first wavelength and a first photoelectric conversion section that photoelectrically converts the light of the first wavelength transmitted through the first filter; a second pixel including a second filter that transmits light of a second wavelength and a second photoelectric conversion section that photoelectrically converts the light of the second wavelength transmitted through the second filter; and a plurality of third pixels each including a light-dispersing section including a structure having a dimension equal to or less than a wavelength of incident light and a third photoelectric conversion section that photo-electrically converts light of a third wavelength transmitted through the light-dispersing section. The first pixel and the second pixel are each adjacent to six of the third pixels. Additionally, at least one embodiment of the present disclosure is directed to a light detecting device comprising a plurality of pixels. The plurality of pixels include first pixels that sense light in a first wavelength range, and a second pixel that senses light in a second wavelength range different than the first wavelength range. At least one embodiment of the present disclosure is directed to a light detecting device including a plurality of pixels comprising first pixels that sense light in a first wavelength range, and a second pixel that senses light in a second wavelength range different than the first wavelength range. The second pixel is surrounded by six pixels of the first pixels. The light detecting device may further include a first layer comprising first nanostructures that redirect light in the second wavelength range incident to the first pixels to the second pixel. According to at least one embodiment of the present disclosure, an electronic apparatus comprises a signal processor and a light detecting device as described above.

### BRIEF DESCRIPTION OF DRAWINGS

FIG. 1 is a diagram illustrating an example of a schematic configuration of an imaging device which is an example of a photodetector according to an embodiment of the present disclosure.

FIG. 2 is a diagram illustrating an example of an arrangement of pixels of the imaging device according to an embodiment of the present disclosure.

FIG. 3 is a diagram illustrating an example of a cross-sectional configuration of the imaging device according to an embodiment of the present disclosure.

FIG. 4 is a diagram illustrating an example of a cross-sectional configuration of the imaging device according to an embodiment of the present disclosure.

FIG. 5 is an explanatory diagram of an example of signaling processing by the imaging device according to an embodiment of the present disclosure.

FIG. 6 is a diagram illustrating an example of an arrangement of pixels of an imaging device according to Modification Example 1 of the present disclosure.

FIG. 7 is a diagram illustrating another example of the arrangement of pixels of the imaging device according to Modification Example 1 of the present disclosure.

FIG. 8 is a diagram illustrating a configuration example of a light-dispersing section of an imaging device according to Modification Example 2 of the present disclosure.

FIG. 9 is a diagram illustrating another configuration example of the light-dispersing section of the imaging device according to Modification Example 2 of the present disclosure.

FIG. 10 is a diagram illustrating another configuration example of the light-dispersing section of the imaging device according to Modification Example 2 of the present disclosure.

FIG. 11 is a diagram illustrating another configuration example of the light-dispersing section of the imaging device according to Modification Example 2 of the present disclosure.

FIG. 12 is a diagram illustrating another configuration example of the light-dispersing section of the imaging device according to Modification Example 2 of the present disclosure.

FIG. 13 is a diagram illustrating another configuration example of the light-dispersing section of the imaging device according to Modification Example 2 of the present disclosure.

FIG. 14 is a diagram illustrating another configuration example of the light-dispersing section of the imaging device according to Modification Example 2 of the present disclosure. [FIG. 15A]FIG. 15A is a diagram illustrating an example of a cross-sectional configuration of an imaging device according to Modification Example 3 of the present disclosure.

FIG. 15B is a diagram illustrating an example of a cross-sectional configuration of the imaging device according to Modification Example 3 of the present disclosure. [FIG. 15C]FIG. 15C is a diagram illustrating an example of a cross-sectional configuration of the imaging device according to Modification Example 3 of the present disclosure. [FIG. 16A]FIG. 16A is a diagram illustrating another example of the cross-sectional configuration of the imaging device according to Modification Example 3 of the present disclosure.

FIG. 16B is a diagram illustrating another example of the cross-sectional configuration of the imaging device according to Modification Example 3 of the present disclosure. [FIG. 16C]FIG. 16C is a diagram illustrating another example of the cross-sectional configuration of the imaging device according to Modification Example 3 of the present disclosure.

FIG. 17 is a block diagram illustrating a configuration example of an electronic apparatus including the imaging device.

FIG. 18 is a block diagram depicting an example of schematic configuration of a vehicle control system.

FIG. 19 is a diagram of assistance in explaining an example of installation positions of an outside-vehicle information detecting section and an imaging section.

FIG. 20 is a view depicting an example of a schematic configuration of an endoscopic surgery system.

FIG. 21 is a block diagram depicting an example of a functional configuration of a camera head and a camera control unit (CCU).

### DESCRIPTION OF EMBODIMENTS

Hereinafter, description is given in detail of embodiments of the present disclosure with reference to the drawings. It is to be noted that the description is given in the following order.
1. Embodiment
2. Modification Examples
3. Application Example
4. Practical Application Examples

### 1. Embodiment

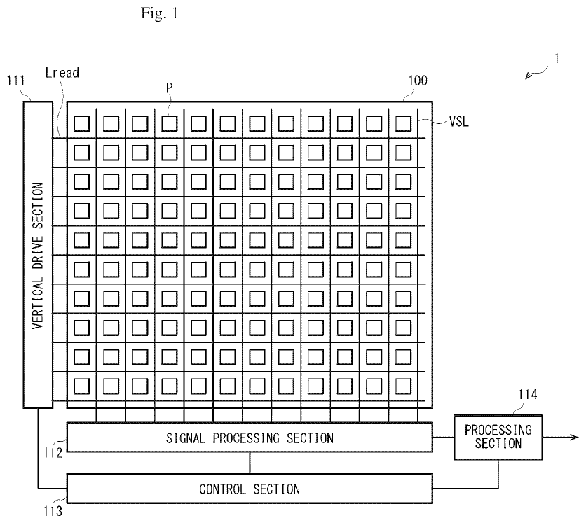

FIG. 1 is a diagram illustrating an example of a schematic configuration of an imaging device which is an example of a photodetector according to an embodiment of the present disclosure. An imaging device 1, which is a photodetector, is a device being able to detect incident light. The imaging device (also called a light detecting device and a photodetector herein) 1 includes a plurality of pixels P each including a light-receiving element, and is configured to photoelectrically convert incident light to generate a signal.

In the example illustrated in FIG. 1, the imaging device 1 includes, as an imaging area, a region (a pixel section 100) in which the plurality of pixels P are two-dimensionally arranged in matrix. The light-receiving element (light-receiving section) of each of the pixel P is, for example, a photodiode. The light-receiving element receives light, and may generate electric charge by photoelectric conversion.

The imaging device 1 takes in incident light (image light) from a subject via an optical system (unillustrated) including an optical lens. The imaging device 1 captures an image of the subject formed by the optical lens system. The imaging device 1 photoelectrically converts the received light to generate a pixel signal. It is to be noted that the imaging device 1, which is a photodetector, is a device being able to receive the incident light to generate a signal; the imaging device 1 can also be referred to as a light-receiving device. The imaging device 1 is usable, for example, for an electronic apparatus such as a digital still camera, a video camera, or a mobile phone.

### Schematic Configuration of Imaging Device

The imaging device 1 includes, in a peripheral region of the pixel section 100, for example, a vertical drive section 111, a signal processing section 112, a control section 113, a processing section 114, and the like. In addition, the imaging device 1 is provided with, for example, a plurality of pixel drive lines Lread and a plurality of vertical signal lines VSL.

As an example, the plurality of pixel drive lines Lread are wired, in the pixel section 100, for respective pixel rows each configured by the plurality of pixels P arranged in a horizontal direction (row direction). In addition, a vertical signal line VSL is wired, in the pixel section 100, for each pixel column configured by the plurality of pixels P arranged in a vertical direction (column direction). The pixel drive line Lread is configured to transmit a drive signal to read a signal from the pixel P. The vertical signal line VSL is configured to transmit a signal outputted from the pixel P.

The vertical drive section 111 is configured by a shift register, an address decoder, and the like. The vertical drive section 111 is configured to drive each pixel P of the pixel section 100. The vertical drive section 111, which is a pixel drive section, generates a signal to drive the pixel P, and outputs the signal to each pixel P of the pixel section 100 via the pixel drive line Lread. The vertical drive section 111 generates, for example, a signal to control a transfer transistor, a signal to control a reset transistor, and the like, and supplies the signal to each pixel P through the pixel drive line Lread.

The signal processing section 112 is configured to perform signal processing of an inputted pixel signal. The signal processing section 112 includes, for example, a load circuit part, an AD converter part, a horizontal selection switch, and the like. The load circuit part is coupled to the vertical signal line VSL, and configures a source follower circuit together with an amplification transistor of the pixel P. It is to be noted that the signal processing section 112 may include an amplification circuit part configured to amplify a signal read from the pixel P via the vertical signal line VSL.

The signal outputted from each pixel P selected and scanned by the vertical drive section 111 is supplied to the signal processing section 112 through the vertical signal line VSL. The signal processing section 112 performs, for example, signal processing such as AD (Analog-to-Digital) conversion and CDS (Correlated Double Sampling: correlated double sampling). The signal of each pixel P transmitted through each of the vertical signal lines VSL is subjected to signal processing by the signal processing section 112, and then outputted to the processing section 114.

The processing section 114 is configured to perform signal processing on an inputted signal. The processing section 114 is configured by, for example, a circuit that performs various types of signal processing on a pixel signal. The processing section 114 may include a processor and a memory. The processing section 114 may perform various types of signal processing on the signal of each pixel, and generate image data (image signal). The processing section 114 can also be referred to as an image signal processing section. The processing section 114 may perform, for example, signal processing such as noise reduction processing or gradation correction processing.

The control section 113 is configured to control each section of the imaging device 1. The control section 113 may receive a clock signal supplied from the outside, data ordering an operation mode, or the like, and output data such as internal information on the imaging device 1. The control section 113 includes a timing generator, and controls driving of the vertical drive section 111 and the signal processing section 112 on the basis of various timing signals (pulse signals, clock signals, and the like). It is to be noted that the control section 113 and the processing section 114 may be integrally configured.

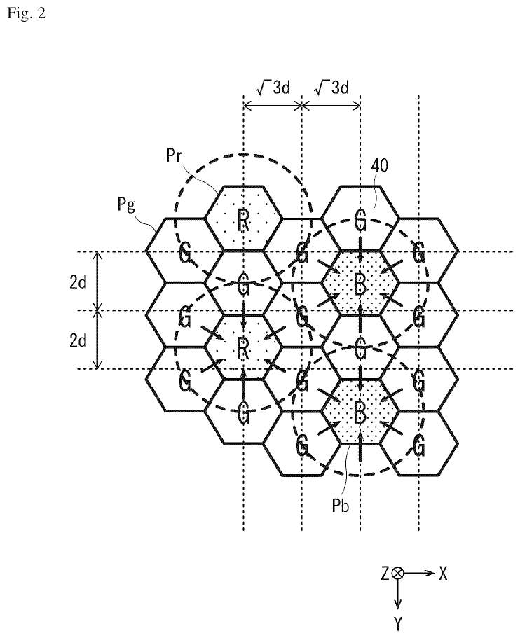

FIG. 2 is a diagram illustrating an example of an arrangement of pixels of the imaging device according to the embodiment. The pixel P of the imaging device 1 includes a color filter 40. It is to be noted that, as illustrated in FIG. 2, a direction of incidence of light from a subject is defined as a Z-axis direction, a horizontal direction on the sheet orthogonal to the Z-axis direction is defined as an X-axis direction, and a vertical direction on the sheet orthogonal to the Z axis and the X axis is defined as a Y-axis direction. In the subsequent figures, a direction may be expressed with reference to the directions of arrows in FIG. 2 in some cases.

The color filter 40 is configured to selectively transmit light of a specific wavelength region (or wavelength range) of incident light. Each pixel includes, for example, a photodiode PD as a photoelectric conversion section (also called a photoelectric conversion region). As illustrated in FIG. 2, the plurality of pixels P provided in the pixel section 100 of the imaging device 1 includes a plurality of pixels Pr, a plurality of pixels Pg, and a plurality of pixels Pb. In the pixel section 100, the plurality of pixels Pr, the plurality of pixels Pg, and the plurality of pixels Pb are repeatedly arranged.

The pixel Pr is a pixel provided with the color filter 40 that transmits red (R) light. The red color filter 40 transmits light of a red wavelength region. A photoelectric conversion section of the pixel Pr receives red wavelength light to perform photoelectric conversion. The pixel Pr is a pixel that receives the light of the red wavelength region to generate a signal. In addition, the pixel Pg is a pixel provided with the color filter 40 that transmits green (G) light. The green color filter 40 transmits light of a green wavelength region. A photoelectric conversion section of the pixel Pg receives green wavelength light to perform photoelectric conversion. The pixel Pg is a pixel that receives the light of the green wavelength region to generate a signal.

The pixel Pb is a pixel provided with the color filter 40 that transmits blue (B) light. The blue color filter 40 transmits light of a blue wavelength region. A photoelectric conversion section of the pixel Pb receives blue wavelength light to perform photoelectric conversion. The pixel Pb is a pixel that receives the light of the blue wavelength region to generate a signal. The pixel Pr, the pixel Pg, and the pixel Pb generate, respectively, a pixel signal of an R component, a pixel signal of a G component, and a pixel signal of a B component. Therefore, it is possible for the imaging device 1 to obtain pixel signals of RGB.

In the present embodiment, each pixel P of the pixel section 100 is provided to be adjacent to six pixels P. The pixel Pr, the pixel Pg, and the pixel Pb are each adjacent to six other pixels in a plane (X-Y plane) of the pixel section 100. It can also be said that each pixel P is positioned among surrounding six pixels and that each pixel P is surrounded by six other pixels. In the example illustrated in FIG. 2, the pixel Pr is arranged adjacent to (or surrounded by) six pixels Pg. In addition, the pixel Pb is also arranged adjacent to (or surrounded by) six pixels Pg. An interval (pitch) between the pixels in the vertical direction (Y-direction) is 2d, and an interval between the pixels in the horizontal direction (X-direction) is √3d.

In addition, the color filter 40 of each pixel P is provided to be adjacent to six color filters 40. The color filter 40 of each of the pixel Pr, the pixel Pg, and the pixel Pb is adjacent to six other color filters 40 in the plane (X-Y plane) of the pixel section 100. It can also be said that each color filter 40 is positioned among surrounding six color filters 40. In the example illustrated in FIG. 2, the color filter 40 of the pixel Pr is arranged adjacent to color filters 40 of six pixels Pg. In addition, the color filter 40 of the pixel Pb is also positioned adjacent to color filters 40 of six pixels Pg. It is to be noted that an interval between the color filters 40 in the vertical direction is 2d, and an interval between the color filters 40 in the horizontal direction is √3d.

As in the example illustrated in FIG. 2, the color filter 40 has one upper side, one lower side, two left sides, and two right sides. In the example illustrated in FIG. 2, the one upper side, the one lower side, the two left sides, and the two right sides are each a linear side. It is to be noted that some or all of the sides of the color filter 40 may be curved.

The pixel P (pixels Pr, Pg, and Pb in FIG. 2) has a hexagonal shape in a plan view. In addition, the color filter 40 of each pixel P has a hexagonal shape in a plan view. The color filters 40 of the respective pixels P are provided in a honeycomb shape. In the example illustrated in FIG. 2, the respective color filters 40 of the pixel Pr, the pixel Pg, and the pixel Pb are arranged in a honeycomb shape. In the pixel section 100 of the imaging device 1, the pixel Pr, the pixel Pg, and the pixel Pb are formed and arranged in a honeycomb shape.

It is to be noted that a corner, which is portion coupling adjacent surfaces (sides) of the color filter 40 together, may include a rounded portion. The corner is a portion that couples a plurality of surfaces configuring the color filter 40, and can also be referred to as a portion at which the plurality of surfaces are in contact with one another. The corner of the pixel P (or color filter 40) may be chamfered, and may include, for example, an arcuate portion.

In addition, as described above, in the present embodiment, there are provided more pixels Pg than pixels Pr or pixels Pb, in consideration of characteristics of human eyes. The number of the pixels Pg is more than the sum of the number of the pixels Pr and the number of the pixels Pb. The pixels Pg are provided to surround the periphery of each of the pixel Pr and the pixel Pb. As illustrated in FIG. 2, the plurality of pixels Pg are provided around the pixel Pr, and the plurality of pixels Pg are also provided around the pixel Pb. Stated another way, a pixel Pr is immediately adjacent to six pixels Pg and a pixel Pb is immediately adjacent to six pixels Pg. As shown in FIG. 2, two pixels Pr may be separated from one another by a single pixel Pb in the y-direction. Similarly, two pixels Pb may be separated from one another by a single pixel Pg. As also shown, a pixel Pr and a pixel Pb may be separated from one another by a single pixel Pg (e.g., in a diagonal direction extending between the x and y directions). A number of pixels Pr may be equal to a number of pixels Pb.

### Configuration of a Pixel

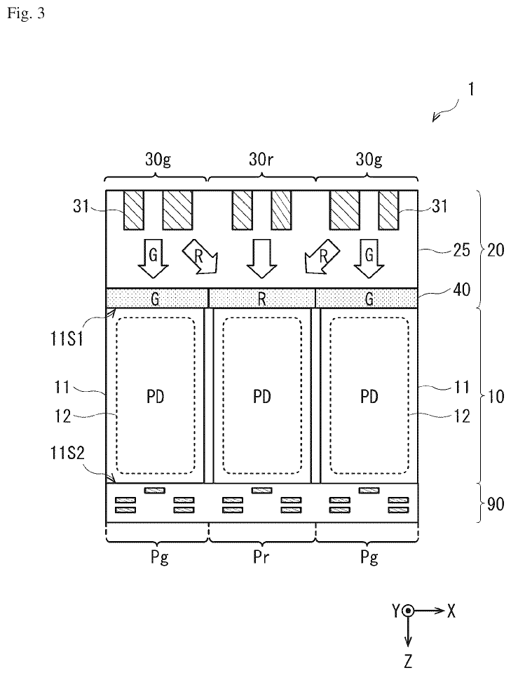

FIG. 3 is a diagram illustrating an example of a cross-sectional configuration of the imaging device according to the embodiment. As illustrated in FIG. 3, the imaging device 1 has a configuration in which, for example, a light-receiving section 10, a light-guiding section 20, and a multilayer wiring layer 90 are stacked in the Z-axis direction.

The light-receiving section 10 includes a semiconductor substrate 11 having a first surface 11S1 and a second surface 11S2 opposed to each other. The light-guiding section 20 is provided on a side of first surface 11S1 of the semiconductor substrate 11, and the multilayer wiring layer 90 is provided on a side of the second surface 11S2 of the semiconductor substrate 11. It can also be said that the light-guiding section 20 is provided on a side on which light from an optical lens system is incident and the multilayer wiring layer 90 is provided on a side opposite to the light incident side. The imaging device 1 is a so-called back-illuminated imaging device.

The semiconductor substrate 11 is configured by, for example, a silicon substrate. A photoelectric conversion section (also called a photoelectric conversion region) 12 may comprise a photodiode (PD) with a p-n junction at a predetermined region of the semiconductor substrate 11. A plurality of photoelectric conversion sections 12 are embedded and formed in the semiconductor substrate 11. In the light-receiving section 10, the plurality of photoelectric conversion sections 12 are provided along the first surface 11S1 and the second surface 11S2 of the semiconductor substrate 11.

The multilayer wiring layer 90 has a configuration in which, for example, a plurality of wiring layer are stacked with an interlayer insulating layer interposed therebetween. The wiring layer of the multilayer wiring layer 90 is formed using, for example, aluminum (Al), copper (Cu), tungsten (W), or the like. In addition thereto, the wiring layer may be formed using polysilicon (Poly-Si). The interlayer insulating layer is formed by, for example, a monolayer film including one of silicon oxide (SiOx), silicon nitride (SiNx), or silicon oxynitride (SiOxNy), or a stacked film including two or more thereof.

There is formed, in the semiconductor substrate 11 and the multilayer wiring layer 90, a circuit (e.g., a transfer transistor, a reset transistor, an amplification transistor, etc.) to read a pixel signal based on electric charge generated by the photoelectric conversion section 12. In addition, for example, the vertical drive section 111, the signal processing section 112, and the like, which are described above, are formed in the semiconductor substrate 11 and the multilayer wiring layer 90.

It is to be noted that the imaging device 1 may include an antireflection film and a fixed-charge film between the color filter 40 and the photoelectric conversion section 12. The fixed-charge film is a film having fixed electric charge, and suppresses generation of a dark current at an interface of the semiconductor substrate 11. The light-guiding section 20 described above may include the antireflection film and the fixed-charge film.

The light-guiding section 20 is stacked on the light-receiving section 10 in a thickness direction orthogonal to the first surface 11S1 of the semiconductor substrate 11. The light-guiding section 20 includes a transparent layer 25, a light-dispersing section 30, and the color filter 40, and guides, and in some cases, redirects light incident to the light dispersing section 30. The transparent layer 25 is a light-transmitting transparent layer, and is formed by, for example, a low refractive index material such as silicon oxide (SiOx) or silicon nitride (SiNx). The light-dispersing section 30 is positioned above the color filter 40.

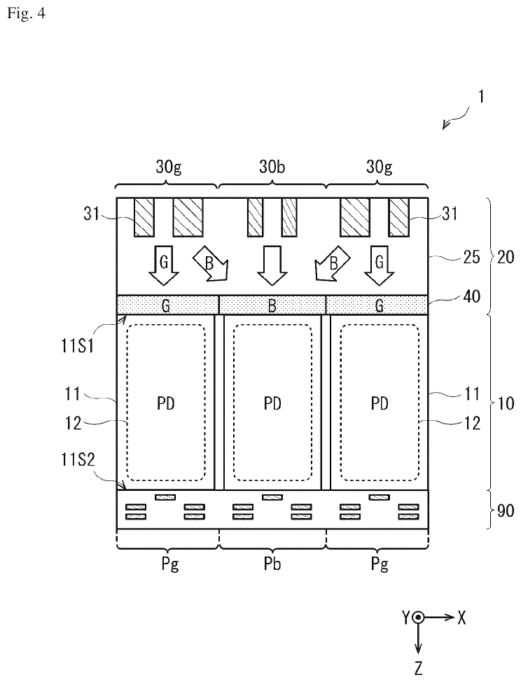

The light-dispersing section 30 includes structures 31 configured to disperse incident light. Each structure 31 may comprise a fine (minute) structure having a dimension equal to or less than a predetermined wavelength of the incident light, for example, a dimension equal to or less than a wavelength of visible light. The structure 31 is a columnar (pillar-shaped) structure, and is provided inside the transparent layer 25. A structure 31 may be referred to as a nanostructure 31. Multiple structures 31 may be referred to as nanostructures 31 herein. The nanostructures 31 may be disposed in the transparent layer 25. Multiple nanostructures 31 may be positioned over each color filter 40 to guide and/or redirect light. As schematically illustrated in FIG. 3, a plurality of structures 31 are arranged side by side in the horizontal direction on the sheet (X-axis direction) in a manner sandwiching a portion of the transparent layer 25. Inside the transparent layer 25, the plurality of structures 31 may be arranged at an interval equal to or less than a predetermined wavelength of incident light, e.g., at an interval equal to or less than a wavelength of visible light. In some cases, the nanostructures 31 may redirect incident light. For example, as shown in FIGS. 3 and 4, nanostructures 31 positioned over pixels Pg may redirect light to a neighboring pixel (e.g., Pb or Pr) sensing a different wavelength range of light.

The structure 31 has a higher refractive index than a refractive index of a peripheral medium. The medium around the structure 31 is, for example, silicon oxide (SiO), air (gap), or the like. In the example illustrated in FIG. 3, the structure 31 is configured by a material having a higher refractive index than a refractive index of the transparent layer 25. The structure 31 is configured by a high refractive index material, and can also be referred to as a high refractive index part. The transparent layer 25 can also be referred to as a low refractive index part.

The structure 31 is formed by using, for example, silicon nitride (SiN). In addition, the structure 31 may be configured by, for example, a silicon compound such as silicon nitride or silicon carbide, a metal oxide such as titanium oxide, tantalum oxide, niobium oxide, hafnium oxide, indium oxide, or tin oxide, or a complex oxide thereof. In addition, the structure 31, which is the high refractive index part, may also be configured by an organic matter such as siloxane.

In this manner, the light-dispersing section 30 is able to cause a phase delay in incident light due to the difference between the refractive index of the structure 31 and the refractive index of the medium therearound, thus affecting a wave front. The light-dispersing section 30 provides a different phase delay amount depending on the wavelength of the light to thereby be able to adjust a direction of propagation of the light and separate the incident light into light beams of respective wavelength regions. A dimension (size), a shape, a refractive index, and the like of each structure 31 are determined to allow the light beams of the respective wavelength regions included in the incident light to travel in desired directions.

The light-dispersing section 30 is a light-dispersing element being able to disperse light by utilizing a meta-material (meta-surface) technology, and can also be referred to as a splitter (color splitter). It can also be said that the imaging device 1 has a color splitter structure. The propagation directions of the light beams of the respective wavelengths by the light-dispersing section 30 can be adjusted by materials (optical constants) of the structure 31 and the transparent layer 25, the shapes and heights of the structures 31, the arrangement interval (gap) between the structures 31, and the like. The light-dispersing section 30 is an optical member that guides (propagates) light.

The light-dispersing section (referred to as a light-dispersing section 30g) of the pixel Pg is configured to be able to propagate green (G) light, of incident light, to the color filter 40 and the photoelectric conversion section 12 of that pixel Pg, and to propagate red (R) light to the color filter 40 and the photoelectric conversion section 12 of the pixel Pr. That is, the light-dispersing section 30g of the pixel Pg splits incident light, and guides light of a red wavelength region of the incident light toward the pixel Pr.

As illustrated in FIG. 3, the light of the red wavelength region, of the light incident on the light-dispersing sections 30g of the pixels Pg around the pixel Pr, travels from the light-dispersing section 30g toward the red color filter 40 and the photoelectric conversion section 12 of the pixel Pr. Therefore, as schematically indicated by dashed circles and arrows in FIG. 2, the plurality of pixels Pg surrounding the pixel Pr is able to guide the light of the red wavelength of the incident light toward the pixel Pr.

The light-dispersing section (referred to as a light-dispersing section 30r) of the pixel Pr is configured to propagate incident light toward the color filter 40 and the photoelectric conversion section 12 of that pixel Pr. The light-dispersing section 30r can also be referred to as a light-guiding section (light-guiding member) that guides the incident light to a side of the color filter 40 of the pixel Pr. The red color filter 40 of the pixel Pr transmits the light of the red wavelength region of the incident light to propagate the light toward the photoelectric conversion section 12.

In this manner, it is possible to guide the light of the red wavelength incident on the pixel Pr and each of the pixels Pg around the pixel Pr to the color filter 40 and the photoelectric conversion section 12 of the pixel Pr. It is possible to condense the light of the red wavelength onto the pixel Pr from the pixels around the pixel Pr. Therefore, the photoelectric conversion section 12 of the pixel Pr may receive incident red wavelength light separated by the light-dispersing section 30g of the pixel Pg and red wavelength light transmitted through the light-dispersing section 30r. It is possible for the photoelectric conversion section 12 of the pixel Pr to efficiently receive the light of the red wavelength region for performing photoelectric conversion and to generate electric charge corresponding to an amount of light reception.

In addition, as illustrated in FIG. 4, the light-dispersing section 30g of the pixel Pg is configured to be able to propagate blue (B) light, of incident light, to the color filter 40 and the photoelectric conversion section 12 of the pixel Pb. That is, the light-dispersing section 30g of the pixel Pg splits the incident light, and guides light of a blue wavelength region of the incident light toward the pixel Pb.

As illustrated in FIG. 4, the light of the blue wavelength region, of the light incident on the light-dispersing sections 30g of the pixels Pg around the pixel Pb, travels from the light-dispersing section 30g toward the blue color filter 40 and the photoelectric conversion section 12 of the pixel Pb. Therefore, as schematically indicated by dashed circles and arrows in FIG. 2, the plurality of pixels Pg surrounding the pixel Pb is able to guide the light of the blue wavelength of the incident light toward the pixel Pb.

The light-dispersing section (referred to as a light-dispersing section 30b) of the pixel Pb is configured to propagate incident light toward the color filter 40 and the photoelectric conversion section 12 of that pixel Pb. The light-dispersing section 30b can also be referred to as a light-guiding section (light-guiding member) that guides the incident light to a side of the color filter 40 of the pixel Pb. The blue color filter 40 of the pixel Pb transmits the light of the blue wavelength region of the incident light to propagate the light toward the photoelectric conversion section 12.

In this manner, it is possible to guide the light of the blue wavelength incident on the pixel Pb and each of the pixels Pg around the pixel Pb to the color filter 40 and the photoelectric conversion section 12 of the pixel Pb. It is possible to condense the light of the blue wavelength onto the pixel Pb from the pixels around the pixel Pb. Therefore, the photoelectric conversion section 12 of the pixel Pb may receive incident blue wavelength light separated by the light-dispersing section 30g of the pixel Pg and blue wavelength light transmitted through the light-dispersing section 30b. It is possible for the photoelectric conversion section 12 of the pixel Pb to efficiently receive the light of the blue wavelength region for performing photoelectric conversion and to generate electric charge corresponding to an amount of light reception.

As described above, the light-dispersing section 30g of the pixel Pg transmits light of the green wavelength region of the incident light to propagate the light toward the color filter 40 and the photoelectric conversion section 12 of that pixel Pg. In the pixels Pg around the pixel Pr, the photoelectric conversion section 12 may receive green wavelength light transmitted through the light-dispersing section 30g and the color filter 40 for performing photoelectric conversion and generate electric charge corresponding to an amount of light reception.

It is to be noted that the structures 31 of above-described light-dispersing section 30g, light-dispersing section 30r, and light-dispersing section 30b may be formed to have different respective dimensions, shapes, and the like, for example. The structures 31 of the light-dispersing sections 30g, 30r, and 30b may be configured using the same material or may be configured using different materials.

As described above, in the imaging device 1 according to the present embodiment, the pixel Pr and the pixel Pb are each provided adjacent to six pixels Pg. The light-dispersing section 30g of the pixel Pg is configured to propagate light from that pixel Pg to the pixel Pr and the pixel Pb by light splitting. There are provided more pixels Pg of a green color, which is a color sensitive to human eyes, thus enabling the imaging device 1 to have high sensitivity to green light. In addition, the photoelectric conversion section 12 of the pixel Pg photoelectrically converts the green wavelength light transmitted through the light-dispersing section 30g which is the light-dispersing section of the pixel Pg. It is possible to enhance a resolution of green (G), as compared with a case of taking in the green wavelength light also from the pixels Pr or the pixels Pb therearound. It becomes possible to improve an S/N ratio of pixel signals of the G component and to enhance the image quality of images.

In addition, in the present embodiment, the light splitting in the light-dispersing section 30g of the pixel Pg allows the red wavelength light to be guided (in this case, redirected) from the pixel Pg to a side of the pixel Pr and the blue wavelength light to be guided (in this case, redirected) from the pixel Pg to a side of the pixel Pb. Therefore, it is possible for the pixel Pr and the pixel Pb to take in light also from the pixels Pg therearound, thus making it possible to enhance sensitivity to incident light. An improvement in quantum efficiency (QE) can be achieved. In addition, a reduction in a difficulty level of design can be expected, as compared with a case of forming the light-dispersing section 30 of each pixel to allow each pixel of RGB to take in light from pixels therearound.

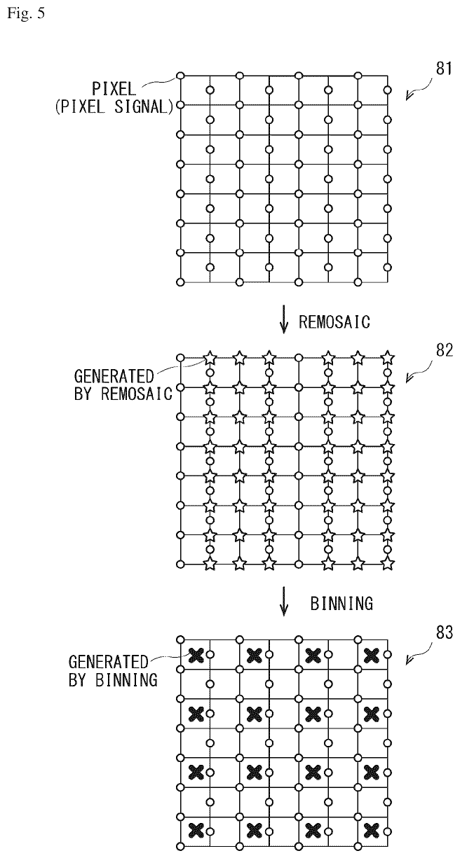

Next, description is given with reference to FIG. 5 of an example of signal processing by the imaging device 1. The processing section 114 of the imaging device 1 performs remosaic processing on RAW image data 81 including pixel signals of the respective pixels P of the pixel section 100. In the remosaic processing, the processing section 114 performs, for example, processing to interpolate a pixel signal corresponding to a position between pixels P adjacent to each other in a vertical direction (or a horizontal direction) using signals of a plurality of pixels therearound. The processing section 114 performs remosaic processing (interpolation processing) on the RAW image data 81 to generate image data 82 as illustrated in FIG. 5.

Then, the processing section 114 performs binning processing on the image data 82. In the binning processing, the processing section 114 adds a plurality of signals of pixels of the same color (e.g., four pixel signals of pixels of the same color). The processing section 114 performs the binning processing on the image data 82 to generate image data 83 as illustrated in FIG. 5. In this manner, the processing section 114 is able to generate image data in a Bayer arrangement. The imaging device 1 is able to output the image data in a Bayer arrangement restored (converted) using the RAW image data 81 to the outside.

### Workings and Effects

The photodetector according to the present embodiment includes a first pixel (e.g., pixel Pr) including a first filter that transmits light of a first wavelength and a first photoelectric conversion section that photoelectrically converts the light of the first wavelength transmitted through the first filter, a second pixel (pixel Pb) including a second filter that transmits light of a second wavelength and a second photoelectric conversion section that photoelectrically converts the light of the second wavelength transmitted through the second filter, and a plurality of third pixels (pixels Pg) each including a light-dispersing section (light-dispersing section 30) including a structure having a dimension equal to or less than a wavelength of incident light and a third photoelectric conversion section that photoelectrically converts light of a third wavelength transmitted through the light-dispersing section. The first pixel and the second pixel are each adjacent to six third pixels.

In the photodetector according to the present embodiment, the pixel Pr and the pixel Pb are each provided adjacent to the six pixels Pg. The light-dispersing section 30g of the pixel Pg is configured to propagate light from that pixel Pg to the pixel Pr and the pixel Pb by light splitting. This enables the photodetector (imaging device 1) to have high sensitivity. It is possible to enhance the resolution of green (G) and thus to enhance the image quality of images. It becomes possible to achieve a photodetector having high detection performance.

Next, description is given of modification examples of the present disclosure. Hereinafter, components similar to those of the foregoing embodiment are denoted by the same reference numerals, and descriptions thereof are omitted as appropriate.

### 2. Modification Examples

### 2-1. Modification Example 1

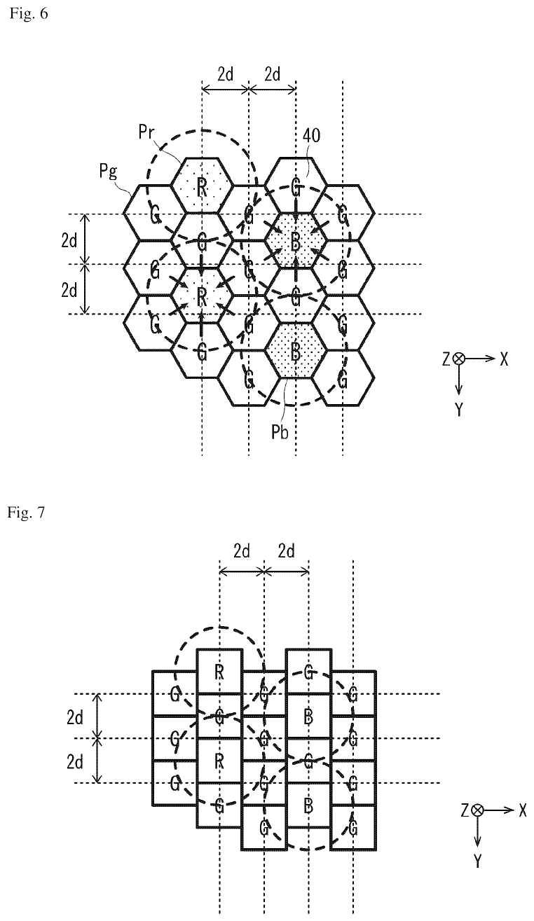

In the foregoing embodiment, the description has been given of the example of the arrangement of pixels, but the arrangement of pixels is not limited thereto. For example, as illustrated in FIG. 6, the pixels P may be arranged to allow an interval between pixels in the vertical direction (Y-direction) and an interval between pixels in the horizontal direction (X-direction) to be identical. In the example illustrated in FIG. 6, the interval between pixels in the vertical direction and the interval between pixels in the horizontal direction are both 2d. An interval between the color filters 40 in the vertical direction and an interval between the color filters 40 in the horizontal direction are both 2d. It is to be noted that the shapes of the pixel P and the color filter 40 can be changed as appropriate, and may each be quadrangular, for example, as illustrated in FIG. 7. Allowing the arrangement interval in the vertical direction and the arrangement interval in the horizontal direction to be substantially equal to each other makes it possible to generate (restore) image data in a Bayer arrangement relatively easily.

### 2-2. Modification Example 2

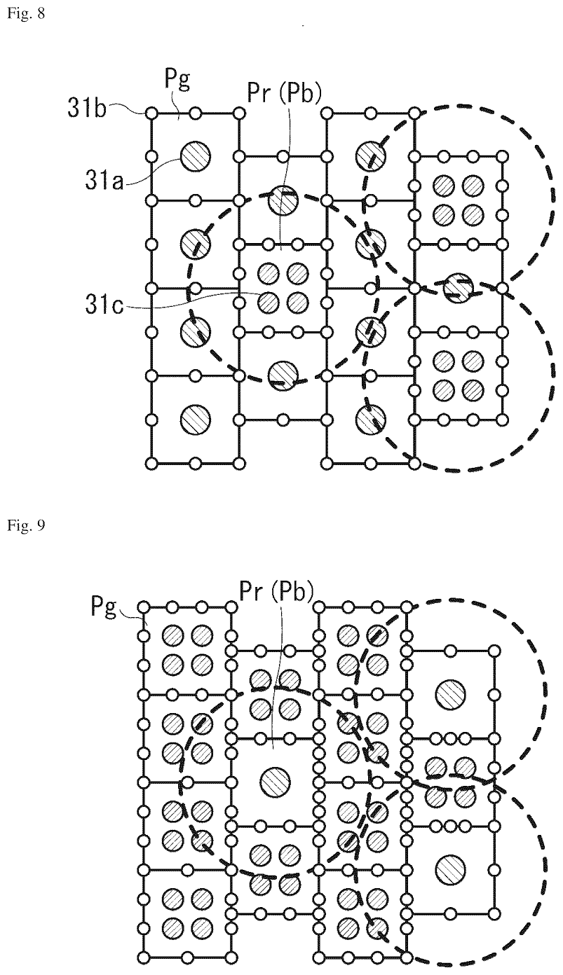

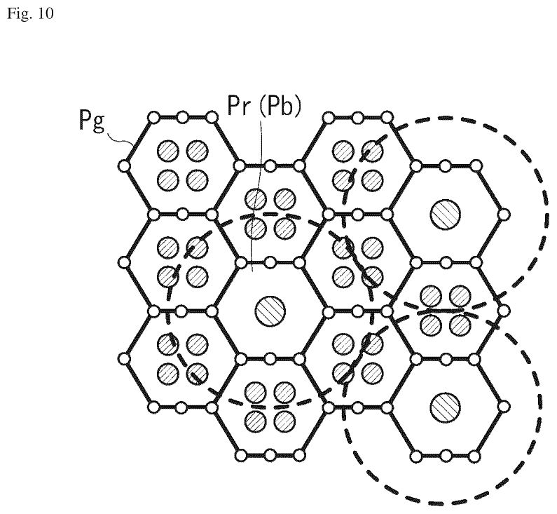

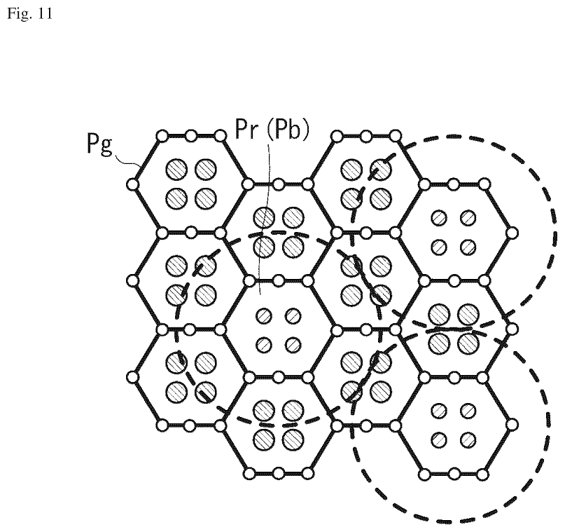

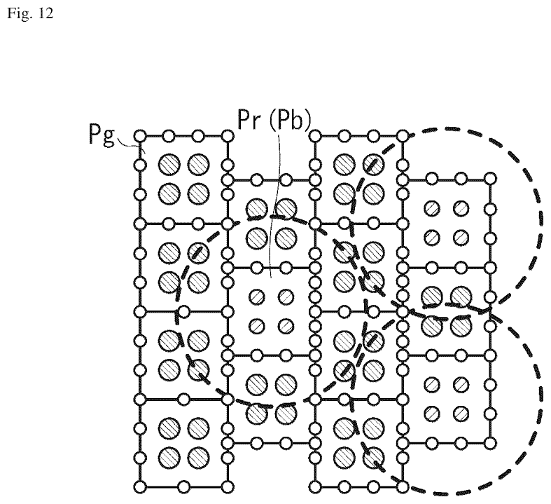

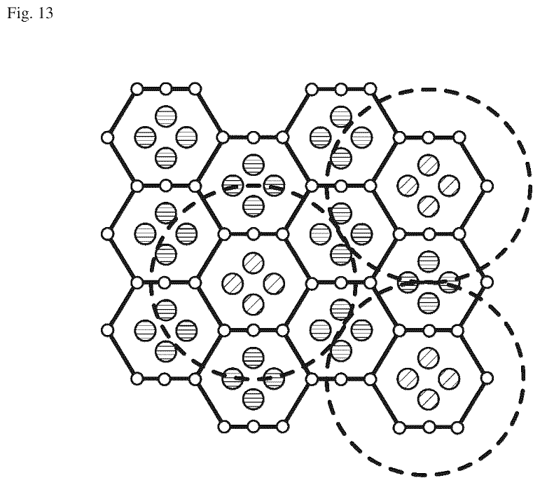

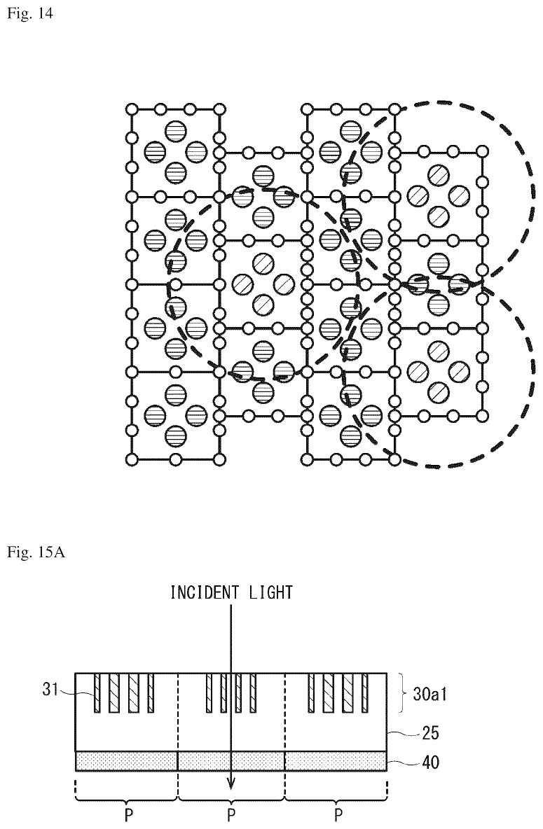

The foregoing embodiment illustrates the configuration example of the light-dispersing section 30 including a fine structure. However, the configuration example is merely illustrative, and the configuration of the light-dispersing section 30 is not limited to the above-described example. For example, as illustrated in FIGS. 8 to 10, the light-dispersing section 30g of the pixel Pg, the light-dispersing section 30r of the pixel Pr, and the light-dispersing section 30b of the pixel Pb may include structures of different numbers and dimensions (e.g., a structure 31a, a structure 31b, and a structure 31c in FIG. 8). In addition, as in examples of FIGS. 11 and 12, the light-dispersing section 30g of the pixel Pg, the light-dispersing section 30r of the pixel Pr, and the light-dispersing section 30b of the pixel Pb may include structures of different dimensions. As illustrated in FIGS. 13 and 14, the structures may be arranged in a manner shifted by 45° relative to the shapes of the pixels in a plan view. In the examples illustrated in FIGS. 13 and 14, a plurality of structures are arranged in a cross shape.

### 2-3. Modification Example 3

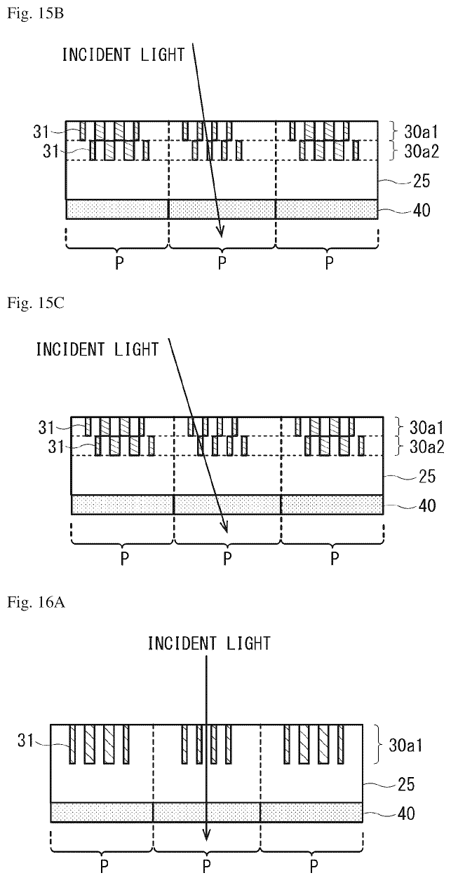

The light-dispersing sections 30 in the respective pixels P may be configured differently depending on a distance from the center of the pixel section 100 (light-receiving section 10), i.e., depending on an image height. As an example, in a region with a low image height, the pixel P includes a first light-dispersing section 30a1, as illustrated in FIG. 15A. FIG. 15B illustrates a region with a higher image height than that in the case of FIG. 15A. FIG. 15C illustrates a region with a higher image height than that in the case of FIG. 15B. As illustrated in FIG. 15B and FIG. 15C, in the region with a high image height, the pixel P includes the first light-dispersing section 30a1 and a second light-dispersing section 30a2, and thus is able to guide oblique incident light appropriately using the light-dispersing sections in two layers. As illustrated, the first light dispersing section 30al includes nanostructures 31 that are offset in a horizontal direction from nanostructures 31 in second light dispersing region 30a2.

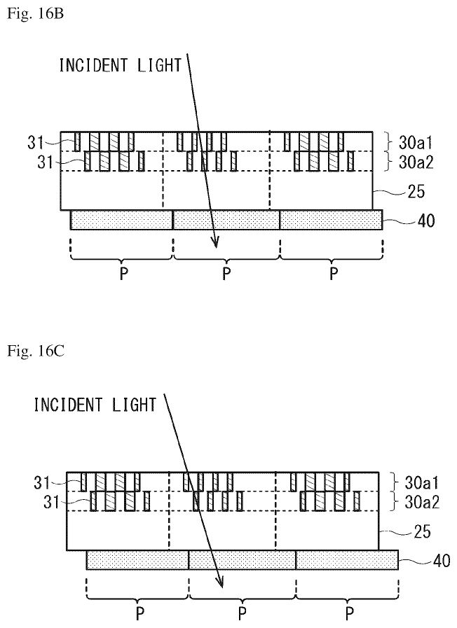

It is to be noted that the color filter 40 and the photoelectric conversion section 12 may be arranged in a shifted manner depending on the image height. FIG. 16B illustrates a region with a higher image height than that in the case of FIG. 16A. FIG. 16C illustrates a region with a higher image height than that in the case of FIG. 16B. As illustrated in FIGS. 16B and 16C, in the region with a high image height, the color filter 40 or the like of the pixel P is arranged in a manner shifted toward the end of the pixel section 100 with respect to the light-dispersing section 30 of that pixel P. In the case of FIG. 16C, the color filter 40 or the like of the pixel P is arranged in a manner shifted toward the end of the pixel section 100 with respect to the light-dispersing section 30 of that pixel P, by a shift amount greater than that in the case of FIG. 16B. In the present modification example, it is possible to adjust the shape of the light-dispersing section 30, the position of the color filter 40 or the like depending on the image height and to perform pupil correction appropriately. It becomes possible to prevent a reduction in sensitivity to incident light.

### 2-4. Modification Example 4

The description has been given of the example of the arrangement of the color filters 40 in the foregoing embodiment, but the arrangement of the color filters 40 is not limited thereto. In the foregoing embodiment, the red wavelength light, of the light incident on the light-dispersing section 30g of the pixel Pg, travels to the side of the pixel Pr, and the blue wavelength light thereof travels to the side of the pixel Pb. Therefore, the pixel Pg may not be provided with the color filter 40.

The filters provided in the pixels P are not limited to primary (RGB) color filters, and may be color filters of complementary colors such as Cy (cyan), Mg (magenta), and Ye (yellow), for example. In addition, a color filter corresponding to W (white), i.e., a filter that transmits light beams of all wavelength regions of incident light may be arranged.

For example, a pixel Py including a Ye (yellow) color filter 40 may be arranged. In this case, the light-dispersing section 30 of the pixel Py may be configured to propagate light from the pixel Py to pixels of other colors (pixel Pr, pixel Pb, etc.) by light splitting. In addition, for example, a pixel Pw including a W (white) color filter 40 may be provided. The light-dispersing section 30 of the pixel Pw may be configured to propagate light from the pixel Pw to pixels of other colors (pixel Pr, pixel Pb, etc.) by light splitting. Also in these cases, it is possible to obtain effects similar to those of the foregoing embodiment.

It is to be noted that the color filter 40 may be omitted as needed. For example, the color filter 40 may not be provided in some or all of the pixels P of the imaging device 1, depending on characteristics of the light-dispersing section 30. The color filter is not essential, and may be omitted depending on design or the like of the light-dispersing section 30.

### 2-5. Modification Example 5

The imaging device 1 may be provided with a lens section (on-chip lens) that condenses light. For example, the lens section may be provided between the light-dispersing section 30 and the color filter 40 for each of the pixels P. The lens section is provided above the color filter 40 to be able to condense light onto the color filter 40 and the photoelectric conversion section 12.

### 3. Application Example

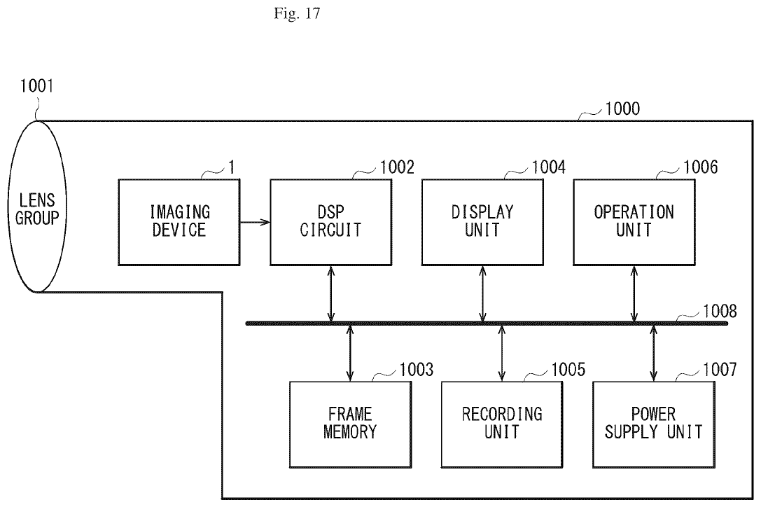

The above-described imaging device 1 or the like is applicable, for example, to any type of electronic apparatus with an imaging function including a camera system such as a digital still camera or a video camera, a mobile phone having an imaging function, and the like. FIG. 17 illustrates a schematic configuration of an electronic apparatus 1000.

The electronic apparatus 1000 includes, for example, a lens group 1001, the imaging device 1, a DSP (Digital Signal Processor) circuit 1002, a frame memory 1003, a display unit 1004, a recording unit 1005, an operation unit 1006, and a power supply unit 1007. They are coupled to each other via a bus line 1008.

The lens group 1001 takes in incident light (image light) from a subject, and forms an image on an imaging surface of the imaging device 1. The imaging device 1 converts the amount of incident light formed as an image on the imaging surface by the lens group 1001 into electric signals on a pixel-by-pixel basis, and supplies the DSP circuit 1002 with the electric signals as pixel signals.

The DSP circuit 1002 is a signal processing circuit that processes signals supplied from the imaging device 1. The DSP circuit 1002 outputs image data obtained by processing the signals from the imaging device 1. The frame memory 1003 temporarily holds the image data processed by the DSP circuit 1002 on a frame-by-frame basis.

The display unit 1004 includes, for example, a panel-type display device such as a liquid crystal panel or an organic EL (Electro Luminescence) panel, and records image data of a moving image or a still image captured by the imaging device 1 in a recording medium such as a semiconductor memory or a hard disk.

The operation unit 1006 outputs an operation signal for a variety of functions of the electronic apparatus 1000 in accordance with an operation by a user. The power supply unit 1007 appropriately supplies the DSP circuit 1002, the frame memory 1003, the display unit 1004, the recording unit 1005, and the operation unit 1006 with various kinds of power for operations of these supply targets.

### 4. Practical Application Examples

### (Example of Practical Application to Mobile Body)

The technology (the present technology) according to the present disclosure is applicable to a variety of products. For example, the technology according to the present disclosure may be achieved as a device mounted on any type of mobile body such as an automobile, an electric vehicle, a hybrid electric vehicle, a motorcycle, a bicycle, a personal mobility, an aircraft, a drone, a vessel, or a robot.

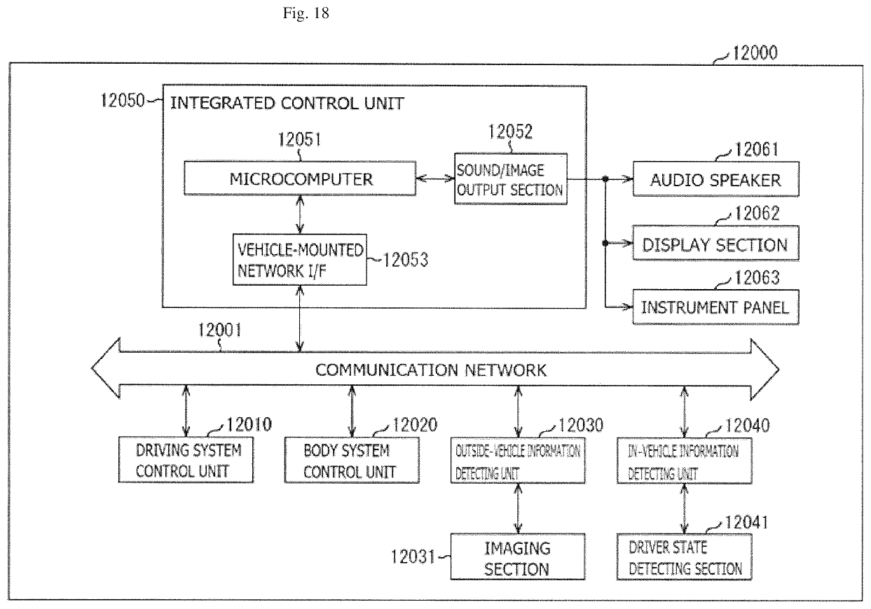

FIG. 18 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 18, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 18, an audio speaker 12061, a display section 12062, and an instrument panel 12063 are illustrated as the output device. The display section 12062 may, for example, include at least one of an on-board display and a head-up display.

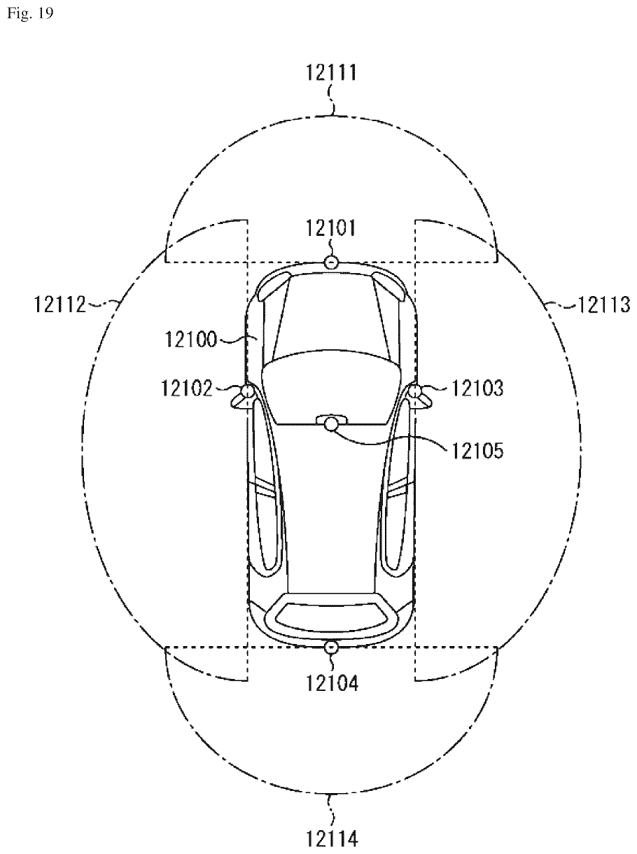

FIG. 19 is a diagram depicting an example of the installation position of the imaging section 12031.

In FIG. 19, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 19 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given hereinabove of the mobile body control system to which the technology according to an embodiment of the present disclosure is applicable. The technology according to an embodiment of the present disclosure is applicable to the imaging section 12031, for example, of the configurations described above. Specifically, for example, the imaging device 1 or the like can be applied to the imaging section 12031. Applying the technology according to an embodiment of the present disclosure to the imaging section 12031 enables obtainment of a photographed image having high definition, thus making it possible to perform highly accurate control utilizing the photographed image in the mobile body control system.

### (Example of Practical Application to Endoscopic Surgery System)

The technology according to an embodiment of the present disclosure (present technology) is applicable to various products. For example, the technology according to an embodiment of the present disclosure may be applied to an endoscopic surgery system.

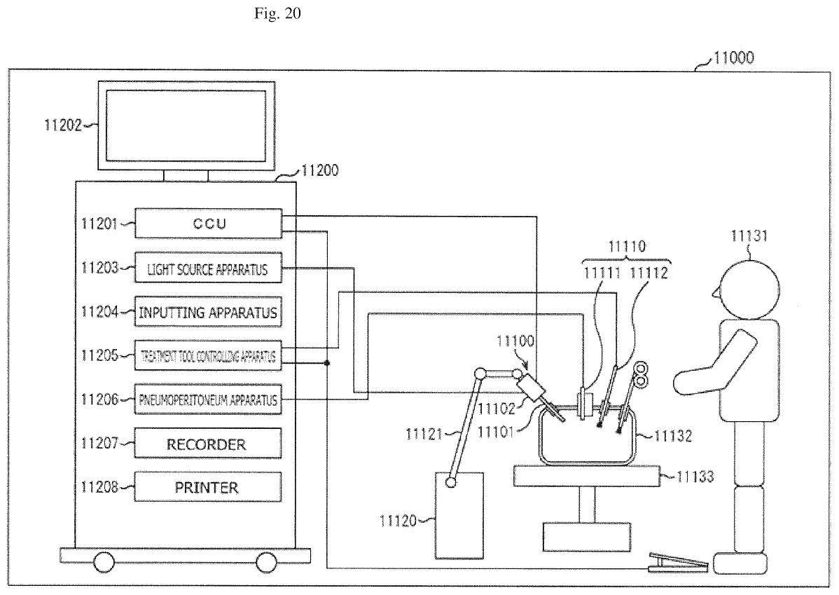

FIG. 20 is a view depicting an example of a schematic configuration of an endoscopic surgery system to which the technology according to an embodiment of the present disclosure (present technology) can be applied.

In FIG. 20, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

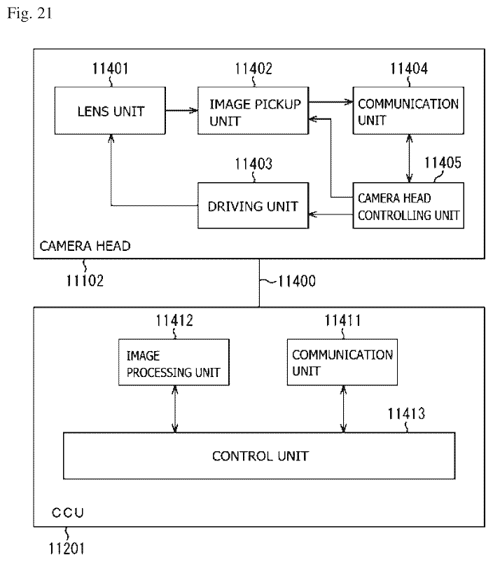

FIG. 21 is a block diagram depicting an example of a functional configuration of the camera head 11102 and the CCU 11201 depicted in FIG. 20.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The description has been given hereinabove of one example of the endoscopic surgery system, to which the technology according to an embodiment of the present disclosure is applicable. The technology according to an embodiment of the present disclosure is suitably applicable to, for example, the image pickup unit 11402 provided in the camera head 11102 of the endoscope 11100 of the configurations described above. Applying the technology according to an embodiment of the present disclosure to the image pickup unit 11402 enables the image pickup unit 11402 to have high sensitivity, thus making it possible to provide the endoscope 11100 having high definition.

In view of the figures and description above, it should be appreciated that at least one embodiment of the present disclosure is directed to a light detecting device 1 comprising a plurality of pixels P. The plurality of pixels include first pixels (e.g., Pg) that sense light in a first wavelength range, and a second pixel (e.g., Pr or Pb) that senses light in a second wavelength range different than the first wavelength range. As shown in the figures, the second pixel is surrounded by six pixels of the first pixels. The light detecting device 1 further comprises a first layer (e.g., layer 25) comprising first nanostructures (e.g., 31) that redirect light incident to the first pixels. The light detecting device may further comprise a third pixel (e.g., Pr or Pb) that senses light in a third wavelength range different than the first and second wavelength ranges. As shown in the figures, the third pixel is surrounded by six pixels of the first pixels. In at least one embodiment, the first pixels comprise pixels having a hexagonal shape in a plan view. In some examples, the light detecting device 1 further comprises first color filters 40 (e.g., G color filters) that pass the first wavelength range for the first pixels. As shown in the figures, the first color filters 40 are positioned between photoelectric conversion regions 12 of the first pixels and the first nanostructures 31. The light detecting device 1 may further comprise a second color filter 40 (e.g., R or B) that passes the second wavelength range for the second pixel. The second color filter 40 is positioned between a photoelectric conversion region 12 of the second pixel and the first layer. In some examples, the light detecting device 1 further includes a third color filter 40 (e.g., R or B) that passes the third wavelength range for the third pixel. The third color filter is positioned between a photoelectric conversion region 12 of the third pixel and the first layer. As shown in the figures, the second color filter is surrounded by six color filters of the first color filters, and the third color filter is surrounded by six color filters of the first color filters. In some examples, the second color filter and the six color filters of the first color filters surrounding the second color filter form a honeycomb shape, and the third color filter and the six color filters of the first color filters surrounding the third color filter form a honeycomb shape. In at least one embodiment, the first nanostructures 31 redirect light incident to the first pixels (e.g., Pg) to the second color filter (e.g., 40R). The photoelectric conversion region 12 of the second pixel receives light passed through the second color filter. The first nanostructures 31 redirect light incident to the first pixels to the third color filter. The photoelectric conversion region of the third pixel receives light passed through the third color filter. In at least one embodiment, the first layer comprises second nanostructures positioned over the second color filter. In some examples, the first layer 25 comprises third nanostructures 31 positioned over the third color filter. In at least one embodiment, the first nanostructures 31 are disposed in a material of the first layer, and the first nanostructures 31 have a higher refractive index than the material. In at least one embodiment, the light detecting device further includes an antireflection film and a fixed-charge film. The antireflection film and the fixed-charge film are disposed between the first nanostructures 31 and color filters 40 of the first pixels. In some examples, the light detecting device 1 includes second nanostructures 31 that redirect light incident to the first pixels, and the second nanostructures 31 are offset from the first nanostructures 31 in a horizontal direction (see FIGS. 15A to 16C). As shown in the figures, the first pixels, the second pixel, and the third pixel may have square shapes in a plan view. At least one embodiment of the present disclosure is directed to a light detecting device including a plurality of pixels comprising first pixels (e.g., Pg) that sense light in a first wavelength range, and a second pixel (e.g. Pr) that senses light in a second wavelength range different than the first wavelength range. As shown in various figures, the second pixel is surrounded by six pixels of the first pixels. The light detecting device 1 may further include a first layer (e.g., 25) comprising first nanostructures 31 that redirect light in the second wavelength range incident to the first pixels to the second pixel. According to at least one embodiment of the present disclosure, an electronic apparatus comprises a signal processor (e.g., DSP 1002) and a light detecting device 1 as described above.

Although the description has been given hereinabove of the present disclosure with reference to particular embodiments, modification examples, application examples, and practical application examples, the present technology is not limited to the foregoing embodiment and the like, and may be modified in a wide variety of ways. For example, although the foregoing modification examples have been described as modification examples of the foregoing embodiment, the configurations of the respective modification examples may be combined as appropriate.

In the foregoing embodiment and the like, the imaging device is exemplified and described; however, it is sufficient for the light detecting device of the present disclosure, for example, to receive incident light and convert the light into electric charge. The signal to be outputted may be a signal of image information or a signal of ranging information.

The light detecting device according to an embodiment of the present disclosure includes a plurality of pixels comprising: first pixels that sense light in a first wavelength range; and a second pixel that senses light in a second wavelength range different than the first wavelength range, the second pixel being surrounded by six pixels of the first pixels; and a first layer comprising first nanostructures that redirect light incident to the first pixels. This makes it possible to achieve a light detecting device having high detection performance. It is to be noted that the effects described herein are merely exemplary and are not limited to the description, and may further include other effects. In addition, the present disclosure may also have the following configurations.

(1)

A photodetector including:
a first pixel including a first filter that transmits light of a first wavelength and a first photoelectric conversion section that photoelectrically converts the light of the first wavelength transmitted through the first filter;
a second pixel including a second filter that transmits light of a second wavelength and a second photoelectric conversion section that photoelectrically converts the light of the second wavelength transmitted through the second filter; and
a plurality of third pixels each including a light-dispersing section including a structure having a dimension equal to or less than a wavelength of incident light and a third photoelectric conversion section that photoelectrically converts light of a third wavelength transmitted through the light-dispersing section, in which
the first pixel and the second pixel are each adjacent to six of the third pixels.

(2)

The photodetector according to (1), in which each of the first filter and the second filter has a hexagonal shape in a plan view.

(3)

The photodetector according to (1) or (2), in which the third pixels each include a third filter that transmits the light of the third wavelength.

(4)

The photodetector according to (3), in which each of the first filter and the second filter is adjacent to six of the third filters.

(5)

The photodetector according to any one of (3) to (4), including a plurality of the first pixels and a plurality of the second pixels, in which
the first filter, the second filter, and the third filter are arranged in a honeycomb shape.

(6)

The photodetector according to any one of (1) to (5), in which the light-dispersing section of each of the third pixels adjacent to the first pixel guides the light of the first wavelength of the incident light to a side of the first photoelectric conversion section.

(7)

The photodetector according to any one of (1) to (6), in which the light-dispersing section of each of the third pixels adjacent to the second pixel guides the light of the second wavelength of the incident light to a side of the second photoelectric conversion section.

(8)

The photodetector according to any one of (1) to (7), in which the first photoelectric conversion section photoelectrically converts light transmitted through the light-dispersing section and the first filter.

(9)

The photodetector according to any one of (1) to (8), in which the second photoelectric conversion section photoelectrically converts light transmitted through the light-dispersing section and the second filter.

(10)

The photodetector according to any one of (3) to (5), in which the third filter transmits light of a green wavelength region as the light of the third wavelength.

(11)

The photodetector according to any one of (1) to (10), in which the first filter transmits light of a red wavelength region as the light of the first wavelength, and
the second filter transmits light of a blue wavelength region as the light of the second wavelength.

(12)

The photodetector according to any one of (1) to (11), in which a refractive index of the structure is higher than a refractive index of a medium adjacent to the structure.

(1a)

A light detecting device, comprising:
a plurality of pixels comprising:
first pixels that sense light in a first wavelength range; and a second pixel that senses light in a second wavelength range different than the first wavelength range, the second pixel being surrounded by six pixels of the first pixels; and
a first layer comprising first nanostructures that redirect light incident to the first pixels.

(2a)

The light detecting device of (1a), wherein the plurality of pixels further comprise: a third pixel that senses light in a third wavelength range different than the first and second wavelength ranges, the third pixel being surrounded by six pixels of the first pixels.

(3a)

The light detecting device of one or more of (1a to 2a), wherein the first pixels comprise pixels having a hexagonal shape in a plan view.

(4a)

The light detecting device of one or more of (1a to 3a), further comprising:
first color filters that pass the first wavelength range for the first pixels, the first color filters being positioned between photoelectric conversion regions of the first pixels and the first nanostructures.

(5a)

The light detecting device of one or more of (1a to 4a), further comprising:
a second color filter that passes the second wavelength range for the second pixel, the second color filter being positioned between a photoelectric conversion region of the second pixel and the first layer.

(6a)

The light detecting device of (5a), further comprising:
a third color filter that passes the third wavelength range for the third pixel, the third color filter being positioned between a photoelectric conversion region of the third pixel and the first layer.

(7a)

The light detecting device of (6a), wherein the second color filter is surrounded by six color filters of the first color filters, and wherein the third color filter is surrounded by six color filters of the first color filters.

(8a)

The light detecting device of (7a), wherein the second color filter and the six color filters of the first color filters surrounding the second color filter form a honeycomb shape, and wherein the third color filter and the six color filters of the first color filters surrounding the third color filter form a honeycomb shape.

(9a)

The light detecting device of one or more of (5a to 8a), wherein the first nanostructures redirect light incident to the first pixels to the second color filter.

(10a)

The light detecting device of one or more of (1a to 9a), wherein the photoelectric conversion region of the second pixel receives light passed through the second color filter.

(11a)

The light detecting device of one or more of (6a to 10a), wherein the first nanostructures redirect light incident to the first pixels to the third color filter.

(12a)

The light detecting device of one or more of (6a to 11a), wherein the photoelectric conversion region of the third pixel receives light passed through the third color filter.

(13a)

The light detecting device of one or more of (5a to 12a), wherein the first layer comprises second nanostructures positioned over the second color filter.

(14a)

The light detecting device of one or more of (6a to 13a), wherein the first layer comprises third nanostructures positioned over the third color filter.

(15a)

The light detecting device of one or more of (1a to 14a), wherein the first nanostructures are disposed in a material of the first layer, and wherein the first nanostructures have a higher refractive index than the material.

(16a)

The light detecting device of one or more of (1a to 15a), further comprising: antireflection film; and
a fixed-charge film, wherein the antireflection film and the fixed-charge film are disposed between the first nanostructures and color filters of the first pixels.

(17a)

The light detecting device of one or more of (1a to 16a), further comprising: second nanostructures that redirect light incident to the first pixels, wherein the second nanostructures are offset from the first nanostructures in a horizontal direction.

(18a)

The light detecting device of one or more of (2a to 17a), wherein the first pixels, the second pixel, and the third pixel have square shapes in a plan view.

(19a)

An electronic apparatus, comprising:
a signal processor; and
a light detecting device, comprising:
a plurality of pixels comprising:
first pixels that sense light in a first wavelength range; and
a second pixel that senses light in a second wavelength range different than the first wavelength range, the second pixel being surrounded by six pixels of the first pixels; and
a first layer comprising first nanostructures that redirect light incident to the first pixels.

(20a)

A light detecting device, comprising:
a plurality of pixels comprising:
first pixels that sense light in a first wavelength range; and
a second pixel that senses light in a second wavelength range different than the first wavelength range, the second pixel being surrounded by six pixels of the first pixels; and
a first layer comprising first nanostructures that redirect light in the second wavelength range incident to the first pixels to the second pixel.

It should be understood by those skilled in the art that various modifications, combinations, sub-combinations and alterations may occur depending on design requirements and other factors insofar as they are within the scope of the appended claims or the equivalents thereof.

### REFERENCE SIGNS LIST

1 imaging device (light detecting device)
12 photoelectric conversion section
30 light-dispersing section
31 structure (nanostructures)
40 color filter

What is claimed is:

1. A light detecting device, comprising:
a plurality of pixels comprising:
first pixels that sense light in a first wavelength range; and
a second pixel that senses light in a second wavelength range different than the first wavelength range, the second pixel being surrounded by six pixels of the first pixels; and
a first layer comprising first nanostructures that redirect light incident to the first pixels.

2. The light detecting device of claim 1, wherein the plurality of pixels further comprise:
a third pixel that senses light in a third wavelength range different than the first and second wavelength ranges, the third pixel being surrounded by six pixels of the first pixels.

3. The light detecting device of claim 1, wherein the first pixels comprise pixels having a hexagonal shape in a plan view.

4. The light detecting device of claim 2, further comprising:
first color filters that pass the first wavelength range for the first pixels, the first color filters being positioned between photoelectric conversion regions of the first pixels and the first nanostructures.

5. The light detecting device of claim 4, further comprising:
a second color filter that passes the second wavelength range for the second pixel, the second color filter being positioned between a photoelectric conversion region of the second pixel and the first layer.

6. The light detecting device of claim 5, further comprising:
a third color filter that passes the third wavelength range for the third pixel, the third color filter being positioned between a photoelectric conversion region of the third pixel and the first layer.

7. The light detecting device of claim 6, wherein the second color filter is surrounded by six color filters of the first color filters, and wherein the third color filter is surrounded by six color filters of the first color filters.

8. The light detecting device of claim 7, wherein the second color filter and the six color filters of the first color filters surrounding the second color filter form a honeycomb shape, and wherein the third color filter and the six color filters of the first color filters surrounding the third color filter form a honeycomb shape.

9. The light detecting device of claim 5, wherein the first nanostructures redirect light incident to the first pixels to the second color filter.

10. The light detecting device of claim 9, wherein the photoelectric conversion region of the second pixel receives light passed through the second color filter.

11. The light detecting device of claim 6, wherein the first nanostructures redirect light incident to the first pixels to the third color filter.

12. The light detecting device of claim 11, wherein the photoelectric conversion region of the third pixel receives light passed through the third color filter.

13. The light detecting device of claim 5, wherein the first layer comprises second nanostructures positioned over the second color filter.

14. The light detecting device of claim 6, wherein the first layer comprises third nanostructures positioned over the third color filter.

15. The light detecting device of claim 1, wherein the first nanostructures are disposed in a material of the first layer, and wherein the first nanostructures have a higher refractive index than the material.

16. The light detecting device of claim 1, further comprising:
antireflection film; and
a fixed-charge film, wherein the antireflection film and the fixed-charge film are disposed between the first nanostructures and color filters of the first pixels.

17. The light detecting device of claim 1, further comprising:
second nanostructures that redirect light incident to the first pixels, wherein the second nanostructures are offset from the first nanostructures in a horizontal direction.

18. The light detecting device of claim 2, wherein the first pixels, the second pixel, and the third pixel have square shapes in a plan view.

19. An electronic apparatus, comprising:
a signal processor; and
a light detecting device, comprising:
a plurality of pixels comprising:
first pixels that sense light in a first wavelength range; and
a second pixel that senses light in a second wavelength range different than the first wavelength range, the second pixel being surrounded by six pixels of the first pixels; and
a first layer comprising first nanostructures that redirect light incident to the first pixels.

20. A light detecting device, comprising:
a plurality of pixels comprising:
first pixels that sense light in a first wavelength range; and
a second pixel that senses light in a second wavelength range different than the first wavelength range, the second pixel being surrounded by six pixels of the first pixels; and
a first layer comprising first nanostructures that redirect light in the second wavelength range incident to the first pixels to the second pixel.
